(19) United States
(12) Patent Application Publication
(10) Pub. No.: US 2023/0168554 A1
(43) Pub. Date: Jun. 1, 2023

(54) DISPLAY DEVICE AND COMPOSITE DISPLAY DEVICE

(71) Applicant: KYOCERA Corporation, Kyoto-shi, Kyoto (JP)

(72) Inventors: Hiroaki ITO, Ritto-shi, Shiga (JP); Yasushi MIYAJIMA, Gifu-shi, Gifu (JP)

(21) Appl. No.: 17/927,633

(22) PCT Filed: May 10, 2021
(86) PCT No.: PCT/JP2021/017672

§ 371 Date: Nov. 23, 2022

(30) Foreign Application Priority Data
May 26, 2020 (JP) 2020-091576

(51) Int. Cl. G02F 1/1362; G09F 9/40

(52) U.S. Cl. CPC G02F 1/136286; G09F 9/40; G02F 2201/123

(57) ABSTRACT

A display device includes a substrate including a first surface, a plurality of pixel units on the first surface, and a first side wiring pad located in a first outermost array adjacent to a first side on the first surface and located between adjacent pixel units of the plurality of pixel units in a direction along the first side. A plurality of pixel units in the first outermost array can be arranged in a portion adjacent to an edge on the first surface of the substrate. A joint pixel pitch can thus be easily equalized to a non-joint pixel pitch, although the non-joint pixel pitch is smaller.

### TECHNICAL FIELD

The present disclosure relates to a display device and a composite display device including multiple display devices that are joined (tiled) to one another.

### BACKGROUND OF INVENTION

A known display device and a known composite display device are described in, for example, Patent Literature 1.

### CITATION LIST

### Patent Literature

Patent Literature 1: Japanese Unexamined Patent Application Publication No. 2019-28284

### SUMMARY

In an aspect of the present disclosure, a display device includes a substrate including a display surface, a plurality of pixel units on the display surface, and a first side wiring pad located in a first outermost array adjacent to a first side on the display surface and located between adjacent pixel units of the plurality of pixel units in a direction along the first side.

In another aspect of the present disclosure, a composite display device includes a plurality of display devices according to the above aspect. The plurality of display devices are joined to one another on side surfaces of the plurality of display devices. The plurality of display devices includes a first display device and a second display device. A portion of a side surface adjoining the first side in the first display device and a portion of a side surface adjoining the first side in the second display device are joined to each other.

### BRIEF DESCRIPTION OF THE DRAWINGS

The objects, features, and advantages of the present disclosure will become more apparent from the following detailed description and the drawings.

FIG. 1A is a simplified partial plan view of a display device according to an embodiment of the present disclosure.

FIG. 1B is a plan view of the display device in FIG. 1A, illustrating the entire back surface of the display device.

FIG. 2A is an entire plan view of a display device according to another embodiment of the present disclosure.

FIG. 2B is an entire plan view of the display device in FIG. 1A.

FIG. 2C is an entire plan view of a display device according to another embodiment of the present disclosure.

FIG. 2D is an entire plan view of a display device according to another embodiment of the present disclosure.

FIG. 3 is an enlarged cross-sectional view taken along section line III-III in FIG. 1A.

FIG. 4 is a simplified partial plan view of a display device according to another embodiment of the present disclosure.

FIG. 5 is an enlarged cross-sectional view taken along section line V-V in FIG. 4.

FIG. 6 is a simplified partial plan view of a display device according to another embodiment of the present disclosure.

FIG. 7 is an enlarged cross-sectional view taken along section line VII-VII in FIG. 6.

FIG. 8 is a plan view of a composite display device according to an embodiment of the present disclosure.

FIG. 9 is a plan view of a composite display device according to another embodiment of the present disclosure.

FIG. 10 is an enlarged plan view of a main part of a display device according to another embodiment of the present disclosure, illustrating part B in FIG. 1A.

FIG. 11 is an enlarged plan view of a main part of a display device according to another embodiment of the present disclosure, illustrating part B in FIG. 1A.

### DESCRIPTION OF EMBODIMENTS

A display device with the structure that forms the basis of a display device according to one or more embodiments of the present disclosure will now be described.

As a display device with a structure that forms the basis of a display device according to one or more embodiments of the present disclosure, a known micro-light-emitting diode display device (hereafter also referred to as a micro-LED display device) includes microchip light-emitting diodes (hereafter also referred to as micro-LEDs) arranged in a matrix on a first surface of a substrate. With a known technique, multiple micro-LED display devices are arranged horizontally, and the side surfaces of the multiple micro-LED display devices are joined (tiled) to one another to form a single large tiling panel (also referred to as a multi-display) to display high-quality images on a large screen (refer to, for example, Patent Literature 1). The micro-LED display device has the structure described below, for example. The micro-LED display device includes a drive including an IC and a flexible wiring substrate that are located on the back surface of a substrate such as a glass substrate. The substrate includes electrode pads located at the edge of the front surface and at the edge of the back surface of the substrate. The substrate also includes, on its side surfaces, side wires located to electrically connect the electrode pads on the front surface and the electrode pads on the back surface of the substrate. The side wires electrically connect wires on the front surface and wires on the back surface. Multiple pixel units including pixel circuits including micro-LEDs and thin-film transistors (TFT) that drive and control the emission of the micro-LEDs are arranged in a matrix on the first surface (a front surface or a display surface) of the micro-LED display device.

When the multiple micro-LED display devices each with the above structure are joined to form a composite display device called a multi-display, a pixel pitch (also referred to as a joint pixel pitch) between the multiple pixel units arranged in the outermost array on the side to be joined in a single micro-LED display device and the multiple pixel units arranged in the outermost array on the side to be joined in another micro-LED display device to be joined to the above single micro-LED display device is to be approximately equal to or the same as the pixel pitch (also referred to as a non-joint pixel pitch) of the multiple pixel units arranged excluding in the outermost array of the micro-LED display devices. When the joint pixel pitch is larger than the non-joint pixel pitch, the continuity of a display image at the joint is likely to decrease. This may cause a viewer to feel discomfort in the display image and the joint to be easily noticeable.

In recent years, pixel pitches in displays including micro-LED display devices have become smaller to form high definition displays. When electrode pads are located outside multiple pixel units arranged in the outermost array on the side to be joined in a single micro-LED display device in a composite display device, the joint pixel pitch tends to be larger than the smaller non-joint pixel pitch. In other words, the joint pixel pitch cannot be easily equalized to the non-joint pixel pitch. Techniques responding to such issues have been awaited.

A light emitting device and a composite display device according to one or more embodiments of the present disclosure will now be described with reference to the accompanying drawings.

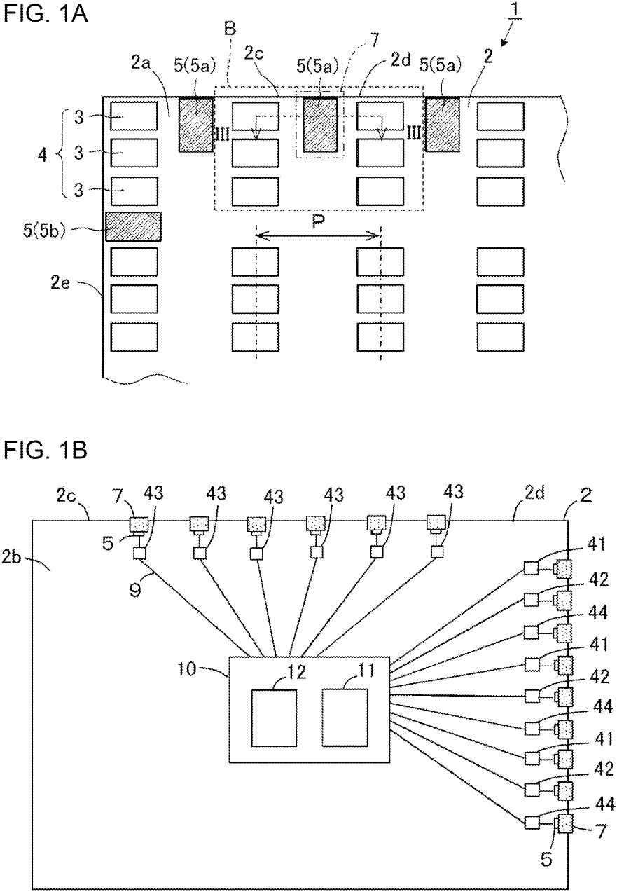

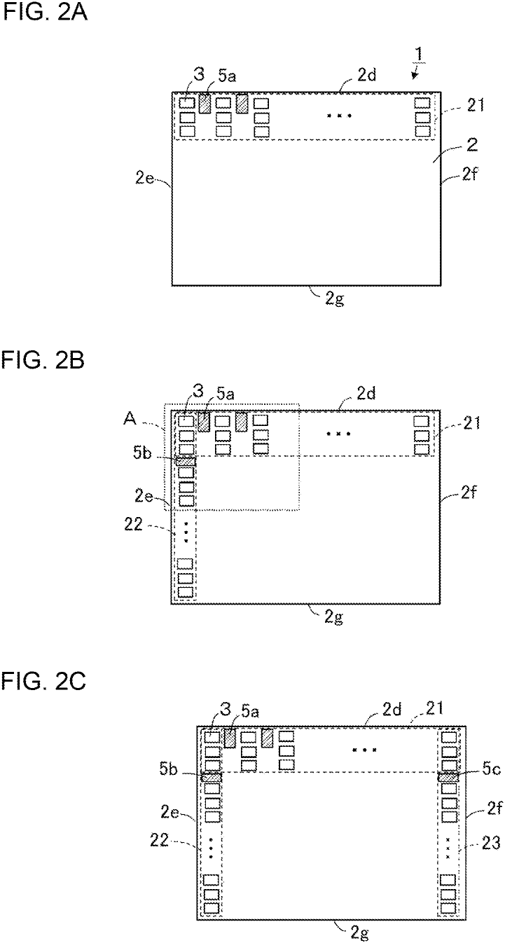

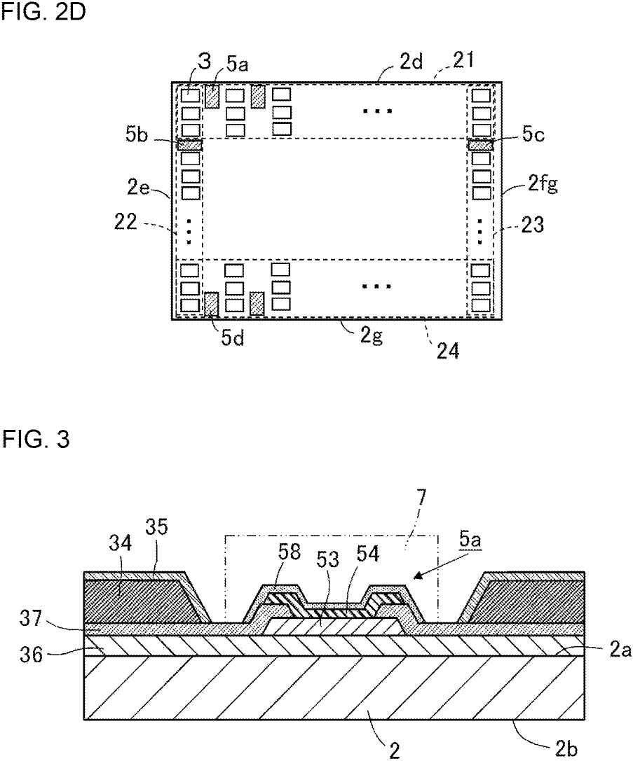

FIG. 1A is a simplified partial plan view of a display device according to an embodiment of the present disclosure. FIG. 1B is a plan view of the display device in FIG. 1A, illustrating the entire back surface of the display device. FIGS. 2A to 2D are entire plan views of the display device according to the embodiments of the present disclosure. FIG. 3 is an enlarged cross-sectional view taken along section line III-III in FIG. 1A. FIG. 1A is an enlarged view of part A of the display device in FIG. 2B.

In the embodiment of the present disclosure, a display device 1 includes a substrate 2 and multiple pixel units 4 located on a first surface (a front surface or a display surface) 2a of the substrate 2. The multiple pixel units 4 may be arranged in a matrix or in a non-matrix manner on the first surface 2a of the substrate 2. An example display device including the multiple pixel units 4 arranged in a matrix is described below. Each pixel unit 4 may include multiple subpixels 3, as illustrated in FIG. 1A. In the example in FIG. 1A, one pixel unit 4 includes three subpixels 3. For example, an uppermost subpixel 3 may be a red pixel including a red light emitter that emits red light, a middle subpixel 3 may be a green pixel including a green light emitter that emits green light, and a lowermost subpixel 3 may be a blue pixel including a green light emitter that emits blue light. Each pixel unit 4 may also include one pixel, for example, a white pixel including a white light emitter that emits white light.

The substrate 2 is, for example, a transparent or opaque glass substrate, a plastic substrate, or a ceramic substrate. The substrate 2 includes the first surface 2a, a second surface (a back surface or a non-display surface) 2b opposite to the first surface 2a, and a side surface 2c (illustrated in FIG. 1A) connecting the first surface 2a and the second surface 2b. The substrate 2 may be a triangular plate, a rectangular plate, a hexagonal plate, or in any other shape. For the substrate 2 being a triangular plate, a rectangular plate, or a hexagonal plate, in particular, for example, multiple display devices may be tiled efficiently. In the present embodiment, the substrate 2 is a rectangular plate in a plan view, as illustrated in, for example, FIG. 2A.

The multiple pixel units 4 are located on the first surface 2a. As illustrated in, for example, FIG. 1A, the pixel units 4 are arranged in a matrix with a predetermined pixel pitch P. The pixel pitch P may be, for example, about 50 to 500 µm or about 100 to 400 µm. Each pixel unit 4 includes an electrode pad and a light emitter electrically connected to the electrode pad. A range of values referred to herein as one value to another value intends to mean the two values being inclusive.

The light emitter is a self-luminous light emitter such as a light-emitting diode (LED), an organic electroluminescence element, or a semiconductor laser element. In the embodiment, the light emitters are LEDs. The light emitters may be micro-LEDs. In this case, the light emitter connected to the electrode pad may be rectangular as viewed in plan with each side having a length of about 1 to 100 µm inclusive, or about 3 to 10 µm inclusive.

The light emitters are electrically connected to the electrode pads with a conductive bonding material such as a conductive adhesive or solder. In the embodiment, the electrode pads include anode pads and cathode pads. Each anode pad is electrically connected to the anode terminal of the light emitter, and each cathode pad is electrically connected to the cathode terminal of the light emitter.

Each pixel unit 4 may include multiple anode pads and cathode pads, and multiple light emitters. The multiple anode pads are electrically connected to the corresponding anode terminals of the light emitters. The multiple cathode pads are electrically connected to the corresponding cathode terminals of the light emitters. The light emitters may include a light emitter that emits red light, a light emitter that emits green light, and a light emitter that emits blue light. In this case, each pixel unit 4 allows display of color gradients. Each pixel unit 4 may include, instead of the light emitter that emits red light, a light emitter that emits orange, red-orange, red-violet, or violet light. Each pixel unit 4 may include, instead of the light emitter that emits green light, a light emitter that emits yellow-green light.

In the embodiment of the present disclosure, the display device 1 may also include multiple side conductors 7 and a back drive 10 including a power supply circuit 11 and a drive control circuit 12 and located on the second surface 2b of the substrate 2, as illustrated in FIG. 1B. The back drive 10 may be a drive element such as an IC or an LSI, or, for example, a circuit board including a drive element. Side wiring pads 5 located on the second surface 2b may be electrically connected to the back drive 10 with, for example, side wires 7 and back wires 9. Each side wiring pad 5 may be electrically connected to a side wiring pad 5 in another display device 1 with the corresponding side wire 7.

As illustrated in, for example, FIG. 1B, the power supply circuit 11 is located on the second surface 2b. The power supply circuit 11 generates a first power supply voltage VDD and a second power supply voltage VSS to be applied to the pixel units 4. The power supply circuit 11 is electrically connected to VDD terminals 41 that output the first power supply voltage VDD and VSS terminals 42 that output the second power supply voltage VSS. The first power supply voltage VDD is an anode voltage of, for example, about 10 to 15 V. The second power supply voltage VSS is lower than the first power supply voltage VDD and is a cathode voltage of, for example, about 0 to 3 V.

The VDD terminals 41 are routed to the first surface 2a through the side wiring pads 5 and the side wires 7 on the back surface and are electrically connected to the anode terminals of the light emitters in the pixel units 4 with the side wiring pads 5 on the front surface. The VSS terminals 42 are routed to the first surface 2a through the side wiring pads 5 and the side wires 7 on the back surface and are electrically connected to the cathode terminals of the light emitters in the pixel units 4 with the side wiring pads 5 on the front surface. On the edge of the side adjoining a first side 2d of the second surface 2b, scanning signal terminals 44 are located in the same terminal array as the VDD terminals 41 and the VSS terminals 42. The scanning signal terminals 44 are electrically connected to the drive control circuit 12, are routed to the first surface 2a through the side wiring pads 5 and the side wires 7 on the back surface, and are electrically connected to the gate electrodes of drive TFTs in the pixel units 4 with the side wiring pads 5 on the front surface. FIG. 1B illustrates the structure including multiple groups each including a VDD terminal 41, a VSS terminal 42, and a scanning signal terminal 44 arranged in the above terminal array. The structure may include a group of multiple VDD terminals 41, a group of multiple VSS terminals 42, and a group of multiple scanning signal terminals 44 arranged in the above terminal array. Another terminal array is located on the edge of the first side 2d of the second surface 2b. The other terminal array includes source signal terminals 43. The source signal terminals 43 are electrically connected to the drive control circuit 12, are routed to the first surface 2a through the side wiring pads 5 and the side wires 7 on the back surface, and are electrically connected to the source electrodes of the drive TFTs in the pixel units 4 with the side wiring pads 5 on the front surface.

The above back drive 10 may include the drive control circuit 12 for controlling, for example, the emission or non-emission state and the light intensity of the light emitters. The back drive 10 may include, for example, a thin film circuit on the second surface 2b of the substrate 2. In this case, the thin film circuit may include, for example, a semiconductor layer including low-temperature polycrystalline silicon (LTPS) formed directly on the second surface 2b by a thin film formation method such as chemical vapor deposition (CVD). The power supply circuit 11 may include an IC chip as a control circuit.

The display device 1 includes a first side wiring pad 5a as a first wiring pad. The first side wiring pad 5a is connected to the corresponding side wire 7 (illustrated in FIG. 3) located on the side surface 2c of the substrate 2. More specifically, the first side wiring pad 5a is connected to an extension of the side wire 7 extending on the first surface 2a. The substrate 2 may be rectangular as illustrated in, for example, FIGS. 1A, 1B, and 2A to 2D. In this case, the substrate 2 includes the first side 2d, a second side 2e adjoining the first side 2d, a third side 2f adjoining the first side 2d and opposite to the second side 2e, and a fourth side 2g opposite to the first side 2d. The first side wiring pad 5a may be located on the first side 2d, a second side wiring pad 5b may be located on the second side 2e, a third side wiring pad 5c may be located on the third side 2f, and a fourth side wiring pad 5d may be located on the fourth side 2g. Thus, for example, the first side wiring pad 5a and other wiring pads are collectively referred to as the side wiring pad(s) 5.

The wiring pad may not be connected to the corresponding side wire 7 and may be connected to a through-conductor, such as a through-hole located at the edge of the substrate 2. Thus, the side wiring pad 5 is one example of the wiring pad. The wiring pads may include wiring pads connected to the side wires 7 and wiring pads connected to the through-conductors.

The first side wiring pad 5a is located between the adjacent pixel units 4 in a direction along the first side 2d in a first outermost array 21 adjacent to the first side 2d of the first surface 2a serving as the display surface. In this case, a portion of the side surface 2c adjoining the first side 2d of the substrate 2 can be used as a joint to be joined to another display device 1 to join at least two display devices 1 to each other to form a composite display device. In this case, the first side wiring pad 5a can be used as a relay for signals transmitted from or to the other display device 1. The signals may be, for example, gate signals (scanning signals), source signals (image signals), or power signals (VDD signals or VSS signals).

The direction along the first side 2d includes a direction parallel to the first side 2d. Thus, the direction along the first side 2d may not be strictly parallel to the first side 2d and may be slightly inclined (e.g., inclined by ±1 to ±5°) to the direction parallel to the first side 2d.

The distance between the pixel unit 3 in the first outermost array 21 and the first side 2d may be less than or equal to one-half of the pixel pitch P of the multiple pixel units 3 (e.g., about 25 to 250 µm). In this structure, when the side surfaces of the multiple display devices 1 are joined to one another, the joint pixel pitch can be more easily equalized to the non-joint pixel pitch P, although the pixel pitch P of the multiple pixel units 3, or the non-joint pixel pitch P, is smaller. The resultant display device can display high-definition images with high quality. This also achieves the continuity of a display image at the joint to allow a viewer to feel less discomfort in the display image and the joint to be less noticeable.

The distance between the first side wiring pad 5a and the first side 2d may be less than or equal to one-half of the pixel pitch P of the multiple pixel units 3, and the first side wiring pad 5a may be nearer the first side 2d than the pixel unit 3 in the first outermost array 21. In this structure, when the side wire formed by applying and firing a conductive paste is located on the side surface 2c adjoining the first side 2d of the substrate 2, the conductive paste is easily placed in the first side wiring pad 5a without being in contact with the pixel unit 3. In the structure described above, the distance between the first side wiring pad 5a and the first side 2d may be about 10 to 15 µm when one-half of the pixel pitch P is 25 µm or may be about 100 to 150 µm when one-half of the pixel pitch P is 250 µm. The distance is not limited to these values.

As illustrated in FIG. 2B, in addition to the first side wiring pad 5a, the second side wiring pad 5b may be located between the adjacent pixel units 4 in a second outermost array 22 adjacent to the second side 2e in a direction along the second side 2e. In this case, a portion of the side surface 2c adjoining the first side 2d of the substrate 2 can be used as a joint to be joined to another display device 1, and a portion of the side surface 2c adjoining the second side 2e of the substrate 2 can be used as a joint to be joined to still another display device 1 to join at least three display devices 1 to one another to form a composite display device. For a rectangular composite display device, at least four display devices 1 may be joined to one another.

As illustrated in FIG. 2C, in addition to the first side wiring pad 5a and the second side wiring pad 5b, the third side wiring pad 5c may be located between the adjacent pixel units 4 in a direction along the third side 2f in a third outermost array 23 adjacent to the third side 2f. In this case, a portion of the side surface 2c adjoining the first side 2d of the substrate 2 can be used as a joint to be joined to another display device 1, a portion of the side surface 2c adjoining the second side 2e of the substrate 2 can be used as a joint to be joined to still another display device 1, and a portion of the side surface 2c adjoining the third side 2f of the substrate 2 can be used as a joint to be joined to still another display device 1 to join at least four display devices 1 to one another to form a composite display device. For a rectangular composite display device, at least six display devices 1 may be joined to one another.

As illustrated in FIG. 2D, in addition to the first side wiring pad 5a, the second side wiring pad 5b, and the third side wiring pad 5c, the fourth side wiring pad 5d may be located between the adjacent pixel units 4 in a direction along the fourth side 2g in a fourth outermost array 24 adjacent to the fourth side 2g. In this case, a portion of the side surface 2c adjoining the first side 2d of the substrate 2 can be used as a joint to be joined to another display device 1, a portion of the side surface 2c adjoining the second side 2e of the substrate 2 can be used as a joint to be joined to still another display device 1, a portion of the side surface 2c adjoining the third side 2f of the substrate 2 can be used as a joint to be joined to still another display device 1, and a portion of the side surface 2c adjoining the fourth side 2g of the substrate 2 can be used as a joint to be joined to still another display device 1 to join at least five display devices 1 to one another to form a composite display device. For a rectangular composite display device, at least nine display devices 1 may be joined to one another.

In the structure illustrated in FIG. 2D, the second side wiring pad 5b and the third side wiring pad 5c may be eliminated. In this case, a portion of the side surface 2c adjoining the first side 2d of the substrate 2 can be used as a joint to be joined to another display device 1, and a portion of the side surface 2c adjoining the fourth side 2g of the substrate 2 can be used as a joint to be joined to still another display device 1 to join at least three display devices 1 to one another to form a composite display device.

The first side wiring pad 5a is located adjacent to the first side 2d on the first surface 2a. In other words, the first side wiring pad 5a is located at the edge on the first side 2d of the substrate 2. The distance between the first side wiring pad 5 and the edge (the first side 2d) of the substrate 2 may be set to about one-half of the pixel pitch (non-joint pixel pitch) of the multiple pixel units 4. For example, when the multiple display devices 1 are joined (tiled) to one another with a light absorber or another component placed in a joint between the adjacent display devices 1, the distance between the first side wiring pad 5a and the edge of the substrate 2 may be set to less than one-half of the pixel pitch of the multiple pixel units 4. As described above, the distance between the first side wiring pad 5a and the edge of the substrate 2 may be less than or equal to one-half of the pixel pitch of the multiple pixel units 4. The first side wiring pad 5a may be multiple first side wiring pads 5a. The second side wiring pad 5b, the third side wiring pad 5c, and the fourth side wiring pad 5d may have the same or similar structure to the above structure of the first side wiring pad 5a.

The pixel unit 4 may be located at least at one end of the first outermost array 21. For example, when another display device 1 is joined to the left of the display device 1 in the structure illustrated in FIG. 2A, the pixel unit 4 may be located at least on the left end of the first outermost array 21. In this case, the distance between the leftmost pixel unit 4 in the first outermost array 21 and the second side 2e can be easily set to less than or equal to about one-half of the non-joint pixel pitch. Likewise, the pixel unit 4 may be located at the other end (right end) of the first outermost array 21. The second outermost array 22, the third outermost array 23, and the fourth outermost array 24 may also have the same or similar structure to the above structure of the first outermost array 21.

The first side wiring pad 5a may have a rectangular shape longer in a direction orthogonal to the first side 2d than in the direction along the first side 2d in a plan view. In this case, the contact area between the first side wiring pad 5a and the corresponding side wire 7 increases to reduce contact resistance. With the side wire 7 formed using a conductive paste, the conductive paste is less likely to flow beyond the first side wiring pad 5a toward a central portion (in a depth direction) of the first surface 2a. To achieve this, for example, a wall or a step including an insulating layer and being higher than the upper surface of the first side wiring pad 5a may be located at the edge of the first side wiring pads 5a nearer the central portion of the first surface 2a or in a portion adjacent to the first side wiring pad 5a and nearer the central portion of the first surface 2a. In this case, the first side wiring pad 5a may have a length in the direction orthogonal to the first side 2d enough to reach the pixel unit 4 in the second outermost array located inward from the first outermost array 21. The first side wiring pad 5a may be, for example, rectangular, trapezoidal, elliptical, or oval in a plan view.

Further, with the side wire 7 formed using a conductive paste, the first side wiring pad 5a may be at a lower position (nearer the first side 2a) than the electrode pads (the anode pad and the cathode pad) in the pixel unit 4 to reduce the likelihood of the conductive paste flowing beyond the first side wiring pad 5a toward the central portion of the first surface 2a (in the depth direction). In this case, for example, the electrode pads in the pixel unit 4 may be located on the insulating layer on the first surface 2a, and the first side wiring pad 5a may not be located on the insulating layer.

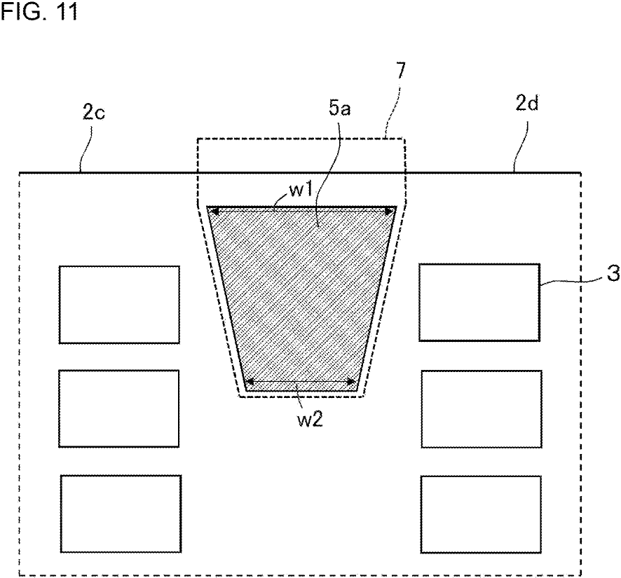

As illustrated in FIG. 10, the first side wiring pad 5a may have a width w1 adjacent to the first side 2d larger than a width w2 opposite to the first side 2d in a plan view. In this structure, when the side wire 7 formed by applying and firing a conductive paste is located on the side surface 2c adjoining the first side 2d of the substrate 2, the conductive paste is easily placed in the first side wiring pad 5a to form the side wire 7 without being in contact with the pixel unit 3. The contact area between the first side wiring pad 5a and the side wire 7 increases to reduce contact resistance. Further, the width of the side wire 7 increases, thus reducing the resistance of the side wire 7. In the structure illustrated in FIG. 10, extending portions 5ae extend along the first side 2d at the end of the first side wiring pad 5a adjacent to the first side 2d. The extending portions 5ae are located on both sides of the end of the first side wiring pad 5a adjacent to the first side 2d in the direction along the first side 2d, but a single extending portion 5ae may be located on one side alone.

As illustrated in FIG. 10, each extending portion 5ae may have a spacing g1 between the extending portion 5ae and the pixel unit 3 nearest the first side 2d in the direction orthogonal to the direction along the first side 2d. This structure can reduce formation of the side wire 7 in contact with the pixel unit 3. The length of each extending portion 5ae in the direction along the first side 2d can also be adjusted easily.

As illustrated in FIG. 11, the first side wiring pad 5a may have the width w1 adjacent to the first side 2d larger than the width w2 opposite to the first side 2d in a plan view and may have a trapezoidal shape. In other words, the first side wiring pad 5a is trapezoidal with the side adjacent to the first side 2d being a lower base and the side opposite to the first side 2d being an upper base. This structure can produce the same or similar effects to the structure illustrated in FIG. 10, and the conductive paste is placed more smoothly in the first side wiring pad 5a and spreads more smoothly in the depth direction of the first side wiring pad 5a.

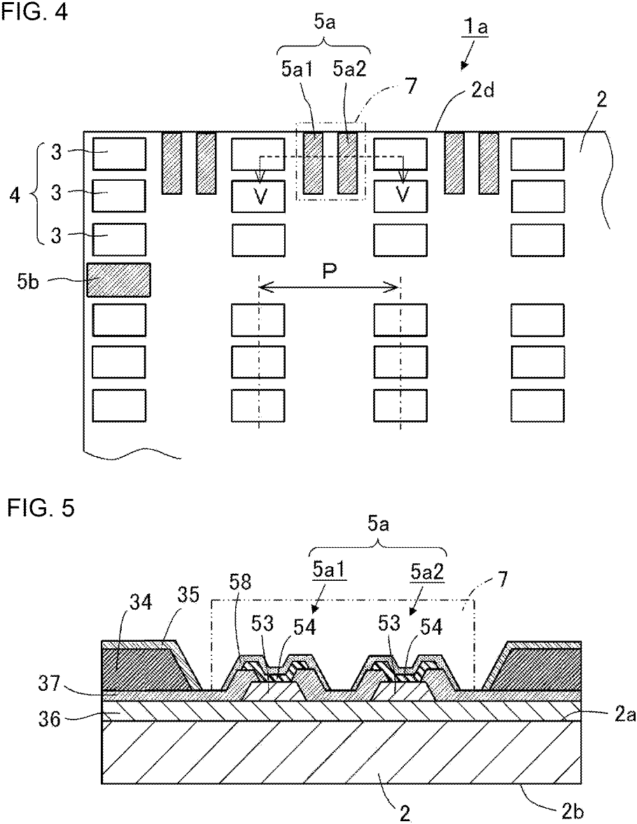

FIG. 4 is a simplified partial plan view of the display device according to another embodiment of the present disclosure. FIG. 5 is an enlarged cross-sectional view taken along section line V-V in FIG. 4. In a display device 1a according to another embodiment of the present disclosure, the first side wiring pad 5a may include multiple side wiring pads and may include a divided side wiring pad 5al and a divided side wiring pad 5a2 as the side wiring pad as illustrated in FIGS. 4 and 5. The divided side wiring pads 5a1 and 5a2 may be aligned in the direction along the first side 2d in a plan view. In this case, the divided side wiring surface pads 5a1 and 5a2 may be connected to a single side wire 7. In some embodiments, the divided side wiring pads 5al and 5a2 may be connected to separate side wires 7. In this case, a single signal can be input into each of the divided side wiring pads 5a1 and 5a2. For example, the divided side wiring pad 5a1 may be a wiring pad for applying the first power supply voltage VDD (positive power supply voltage) to the multiple pixel units 4, and the divided side wiring pad 5a2 may be a wiring pad for applying the second power supply voltage VSS (negative power supply voltage) to the multiple pixel units 4.

The display device 1 or 1a includes a first wiring pattern and a second wiring pattern. The first wiring pattern and the second wiring pattern are located on the first surface 2a. The first wiring pattern and the second wiring pattern include, for example, Mo/Al/Mo or Mo-Nd/Al-Nd/Mo-Nd. The stack of Mo/Al/Mo includes a Mo layer, an Al layer, and a Mo layer stacked in this order. Mo-Nd is an alloy of Mo and Nd. The first wiring pattern may be, for example, a pattern of scanning signal lines (gate signal lines) and VDD wires. The second wiring pattern may be, for example, a pattern of image signal lines (source signal lines) and VSS wires. The scanning signal lines (gate signal lines) are connected to the gate electrodes of the drive TFTs in the pixel circuits included in the pixel units 4. The image signal lines (source signal lines) are connected to the source electrodes of the drive TFTs.

As illustrated in, for example, FIGS. 3 and 5, the first wiring pattern connects the multiple pixel units 4 and the multiple side wiring pads 5a1, and the second wiring pattern connects the multiple pixel units 4 and the multiple side wiring pads 5a2. The first wiring pattern and the second wiring pattern may be planar wiring patterns. In this case, the first wiring pattern and the second wiring pattern are electrically insulated by insulating layers 34 and 37 between them. The first wiring pattern may include the anode pad connected to the anode terminal of the micro-LED.

As illustrated in FIG. 1B, the display device 1 includes the side wires 7 that are located on the second surface 2b from the first surface 2a through the side surface 2c and connected to the side wiring pads 5. The side wiring pads 5 on the back surface that are connected to the side wires 7 may be located on the second surface 2b. Each side wire 7 may include a main portion on the side surface 2c, a first extension extending on the first surface 2a, and a second extension extending on the second surface 2b. The side wires 7 thus electrically connect the side wiring pads 5 on the front surface to the side wiring pads 5 on the back surface. The side wires 7 may be a single or multiple side wires 7 corresponding to the number of side wiring pads 5. The side wiring pads 5 on the back surface may be electrically connected to the back drive with, for example, back wires.

When the first side wiring pad 5a includes the divided side wiring pad 5a1 and the divided side wiring pad 5a2 as in the display device 1a in FIGS. 4 and 5, divided side wiring pads on the back surface may be located on the second surface 2b of the substrate 2 corresponding to the divided side wiring pad 5a1 and the divided side wiring pad 5a2. One side wire 7 may connect the divided side wiring pad 5a1 on the front surface to the corresponding divided side wiring pad on the back surface, and another side wire 7 may connect the divided side wiring pad 5a2 on the front surface to the corresponding divided side wiring pad on the back surface.

The substrate 2 includes insulating layers 34 to 37 on the first surface 2a as illustrated in, for example, FIG. 3. The insulating layers 34 to 37 are inorganic insulating layers made of, for example, SiO₂ or Si₃N₄ or organic insulating layers made of, for example, an acrylic resin or polycarbonate. Although not illustrated, switching elements for controlling the emission state or non-emission state of the light emitters and TFTs as controllers for controlling the luminance are located inside the insulating layer 36 that is nearest the substrate 2 of the insulating layers 34 to 37 or between the substrate 2 and the insulating layer 36.

When the light emitter is a micro-LED, the anode terminal of the micro-LED is electrically connected to the anode pad (not illustrated) included in the first wiring pattern, and the cathode terminal of the micro-LED is electrically connected to the cathode pad (not illustrated) located in the opening in the first wiring pattern. The anode pad and the cathode pad are electrically insulated from each other by the opening in the first wiring pattern around the anode pad. The cathode pad is routed along the surfaces of the insulating layers 34 and 35 and the inner wall of the opening in the insulating layers 34 and 35 and electrically connected to the second wiring pattern. The anode pad and the cathode pad may have their surfaces coated with a transparent conductive layer of, for example, indium tin oxide (ITO) or indium zinc oxide (IZO).

The side wiring pad 5 is made of a conductive material. The side wiring pad 5 may be a single metal layer or multiple metal layers stacked on one another. The side wiring pad 5 is made of, for example, Al, Al/Ti, Ti/Al/Ti, Mo, Mo/Al/ Mo, Mo-Nd/Al-Nd/Mo-Nd, Cu, Cr, Ni, or Ag. In FIGS. 3 and 5, the first side wiring pad 5a includes two metal layers 53 and 54 stacked on each other and is located on the insulating layer 36 on the first surface 2a of the substrate 2.

When the side wiring pad 5 includes the multiple metal layers 53 and 54 stacked on each other, an insulating layer may be located partly between the metal layers 53 and 54. The side wiring pad 5 may include an insulating layer at its inward end on the first surface 2a. This reduces short-circuiting between the first side wiring pad 5 and a wiring conductor or another component located inward on the first surface 2a. These insulating layers are made of, for example, SiO₂, Si₃N₄, or a polymeric material such as an acrylic resin. The first side wiring pad 5 may have its surface coated with a transparent conductive layer 58 (illustrated in FIGS. 3 and 5) of, for example, ITO or IZO.

The side wire 7 may include a conductive paste containing conductive particles of, for example, Ag, Cu, Al, or stainless steel, an uncured resin component, an alcohol solvent, and water. The conductive paste may be applied to an intended portion from the side surface 2c to the first surface 2a and to the second surface 2b and cured by heating, photocuring using ultraviolet ray irradiation, or a combination of photocuring and heating. The side wire 7 may also be formed by a thin film formation method such as plating, vapor deposition, or CVD. The side surface 2c may include a preformed groove in the portion to receive the side wire 7. This allows the conductive paste that forms the side wire 7 to be easily received in the intended portion on the side surface 2c. A coating layer (overcoat layer) of, for example, a resin material may cover and protect the side wire 7.

In the display device 1, the first side wiring pad 5 is located adjacent to the first side 2d between the adjacent two pixel units 4 in the direction in which the first side 2d that is one side of the substrate 2 extends in a plan view. This allows the pixel units 4 in the first outermost array 21 in the multiple pixel units 4 arranged in a matrix to have the joint pixel pitch equal to the pixel pitch (non-joint pixel pitch) P. Thus, when the multiple display devices 1 are joined to one another to form a composite display device (multi-display), the pixel pitch (joint pixel pitch) between one display device 1 and another display device 1 can be substantially equalized to the pixel pitch P of the display device 1. The resultant multi-display can have higher display performance.

Multiple first side wiring pads 5a may all be located at an equal distance from the first side 2d. In this case, at least a portion of each first side wiring pad 5a is located inside a display unit including the multiple pixel units 4 arranged in a matrix. This easily reduces or eliminates the frame around the display unit. For the multi-display, the joint between the display devices 1 can be less noticeable, and the multi-display can have higher display performance.

In the display device 1, the first side wiring pads 5 may be located adjacent to the first side 2d at a predetermined distance from the first side 2d. For manufacturing the display device 1 with this structure, the mother substrate is cut into substrate segments with a laser beam irradiating the second surface 2b with less thermal damage to the first side wiring pads 5a. Each substrate segment cut from the mother substrate includes a display device area to be the display device 1. The display device 1 can thus be manufactured with high yield.

Although not illustrated, the display device 1 includes multiple gate signal lines and multiple source signal lines intersecting with the multiple gate signal lines on the first surface 2a. Each pixel unit 4 includes a first electrode pad connected to the corresponding gate signal line, a second electrode pad connected to the corresponding source signal line, and a TFT for driving the light emitter connected to the first electrode pad and the second electrode pad. Although not illustrated, the display device 1 includes, on the second surface 2b, multiple third electrode pads electrically connected to the first electrode pads, and multiple fourth electrode pads electrically connected to the second electrode pads.

The first electrode pads and the third electrode pads may be electrically connected to each other with, for example, the corresponding side wires 7. The second electrode pads and the fourth electrode pads may be electrically connected to each other with, for example, the corresponding side wires 7. The third electrode pads may be connected to the gate signal line drive circuit (gate drive) located on the second surface 2b with, for example, back wiring. The fourth electrode pads may be connected to the source signal line drive circuit (source drive) located on the second surface 2b with, for example, back wiring. The gate signal line drive circuit and the source signal line drive circuit may be included in the back drive.

The first and second electrode pads in the pixel units 4 included in the outermost arrays 21 to 24 on the first surface 2a may be spaced from the first side 2d, the second side 2e, the third side 2f, and the fourth side 2 g in a plan view by substantially the same distance in a plan view.

The side wiring pad 5 may be formed by photolithography, etching, or another method. The multiple side wiring pads 5 may be arranged on the first surface 2a of the substrate 2 at the same distance from the side of the first surface 2a. This facilitates, for example, formation of the mask pattern or positioning of the mask pattern with respect to the substrate 2. The side wiring pads 5 can thus be formed with high positional accuracy, and the frame can be easily reduced. The resultant display device 1 can have higher display performance.

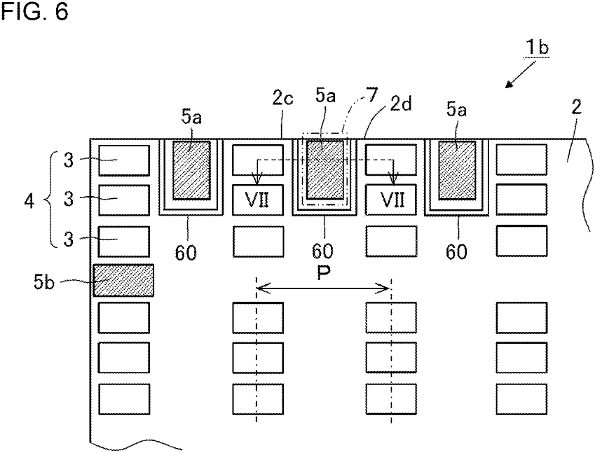

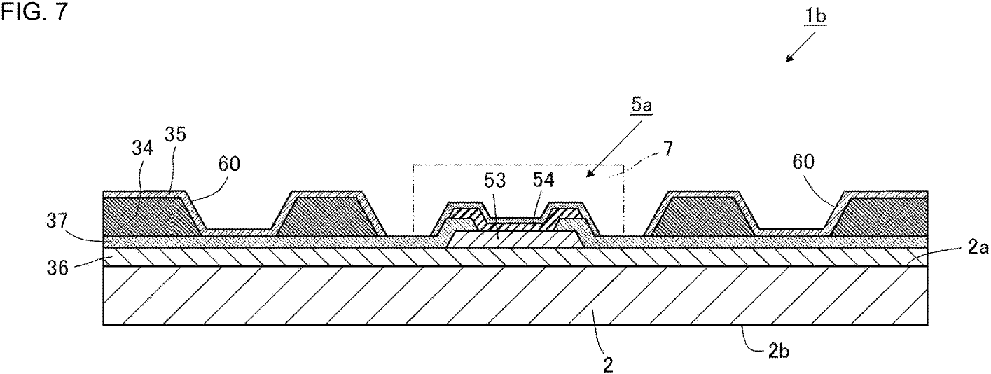

FIG. 6 is a simplified partial plan view of a display device according to another embodiment of the present disclosure. FIG. 7 is an enlarged cross-sectional view taken along section line VII-VII in FIG. 6. The components corresponding to those in the above embodiments are given the same reference numerals. In a display device 1b according to the present embodiment, a portion between the first side wiring pad 5a and the pixel unit 4 located adjacent to the first side wiring pad 5a may be covered with the insulating layers 34, 35, and 37. This structure can effectively reduce short-circuiting between the first side wiring pad 5a and the pixel unit 4 located adjacent to the first side wiring pad 5a. In the present embodiment, the display device 1b may include a recess 60 on the insulating layers 34 and 35 between the first side wiring pad 5a and the pixel unit 4 located adjacent to the first side wiring pad 5a. In this case, for example, a conductive paste for the side wires 7 and a resin paste for the overcoat layer covering the side wires 7 may be applied on the first side wiring pad 5a. In this structure, although the amount of the conductive paste or the resin paste is larger than an intended amount, the excess accumulates in the recess 60 and is less likely to spread from the recess 60 to the surrounding area. This structure can reduce contact of the conductive paste with, for example, the electrode pads of the light emitters.

The various suitable structures for the first side wiring pad 5a described above are applicable to the second side wiring pad 5b, the third side wiring pad 5c, and the fourth side wiring pad 5d.

In one or more embodiments of the present disclosure, the composite display device includes the multiple display devices 1 joined to one another on their side surfaces. The display devices 1 include a first display device and a second display device. A portion of the side surface 2c of the first display device adjoining the first side 2d (the side on which the side wiring pad 5 is located) is joined to a portion of the side surface 2c of the second display device adjoining the first side 2d (fourth side 2g when the side wiring pad 5 is located on the fourth side 2g). This structure can achieve the continuity of a display image at the joint and allows a viewer to feel less discomfort in the display image and the joint to be less noticeable. The joining member that joins the side surfaces of the multiple display devices 1 together may be a resin adhesive, for example, a resin adhesive with a light-shielding color of, for example, black. The joining member may be a mechanical joining member such as a screw. The joining member may use fitting engagement between a protrusion on an end of one substrate 2 and a recess on an end of another substrate 2. The recess is complementary to the protrusion.

A light absorber may be located between a portion (hereafter also referred to as a first joint) of the side surface 2c to be joined in the first display device and a portion (hereafter also referred to as a second joint) of the side surface 2c to be joined in the second display device. The light absorber is formed by, for example, applying a photocurable resin or a thermosetting resin containing a light absorbing material to the first and second joints and curing the resin. The light absorbing material may be, for example, an inorganic pigment. Examples of the inorganic pigment include a carbon pigment such as carbon black, a nitride pigment such as titanium black, and a metal oxide pigment such as a chromium-iron-cobalt (Cr—Fe—Co) pigment, a copper-cobalt-manganese (Cu—Co—Mn) pigment, an iron-cobalt-manganese (Fe—Co—Mn) pigment, or an iron-cobalt-nickel-chromium (Fe—Co—Ni—Cr) pigment.

The light absorber may include an uneven surface that absorbs incident light. For example, the light absorber may be a light absorbing film and may be a black film formed by mixing a black pigment such as carbon black in a base material such as a silicone resin, and unevenness with an arithmetic mean roughness of about 10 to 50 µm or specifically about 20 to 30 µm may be formed on the surface of the black film by, for example, a transfer method. This structure greatly increases the light absorbing effect.

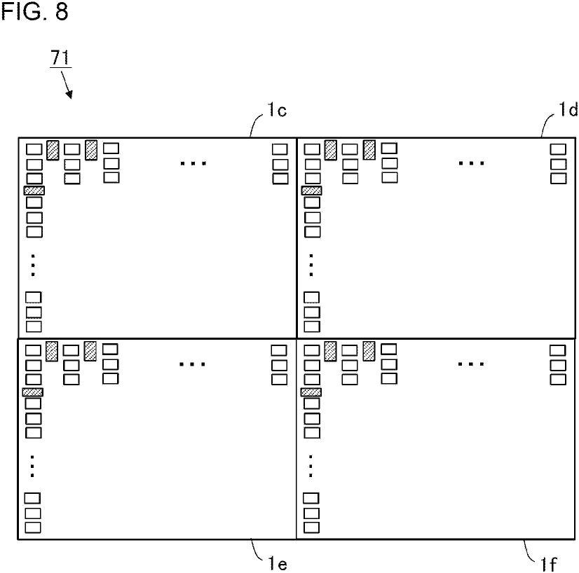

FIG. 8 is a plan view of a composite display device 71 according to one or more embodiments the present disclosure including four display devices 1c, 1d, 1e, and 1f (display devices including the structure illustrated in FIG. 2B) joined to one another. The four display devices 1 are joined to one another by, for example, bonding the side surfaces of the display devices 1 together using an adhesive such as a resin adhesive, bonding a single display device 1 on a single substrate and mechanically fixing the substrates together using, for example, a screw, or fitting a single display device 1 into a single frame and mechanically fixing the frames together using, for example, a screw. In some embodiments, a frame including four openings may be prepared, and the display devices 1 may be fitted and bonded to the corresponding openings. The composite display device 71 includes the display devices illustrated in FIGS. 2A to 2D that are moved in parallel to be arranged at four respective positions and are joined to one another. The distance between each pixel unit 4 arranged in the outermost array adjacent to the side (also referred to as a joint side) to be joined to the display device 1d on the first surface 2a of the substrate 2 in the display device 1c and the joint side may be about one-half of the non-joint pixel pitch. The same or similar structure may be used for the pixel units 4 arranged in the outermost array adjacent to the joint side that is joined to the display device 1e on the first surface 2a of the substrate 2 in the display device 1c. The same or similar structure may be used for the pixel units 4 arranged in the outermost array adjacent to the joint side that is joined to the display device 1f on the first surface 2a of the substrate 2 in the display device 1d. The same or similar structure may be used for the pixel units 4 arranged in the outermost array adjacent to the joint side that is joined to the display device 1f on the first surface 2a of the substrate 2 in the display device 1e.

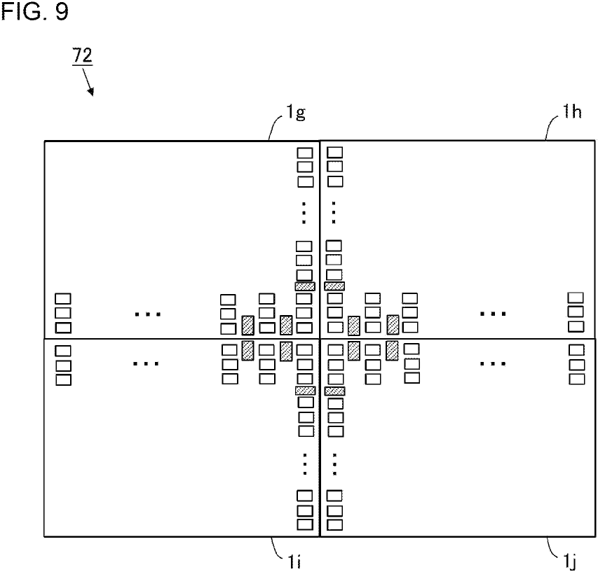

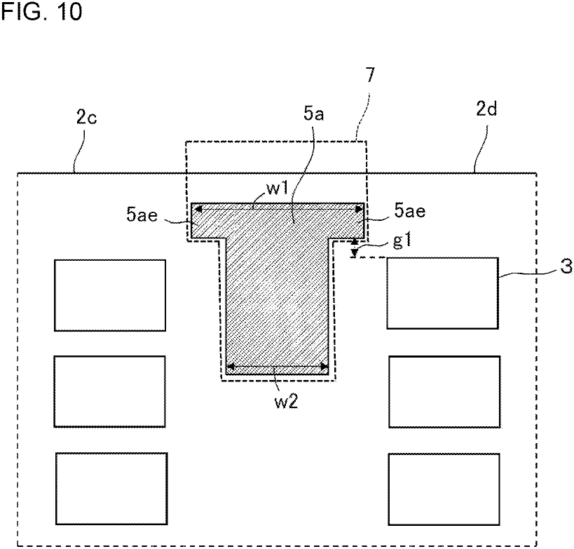

FIG. 9 is a plan view of a composite display device 72 according to another embodiment of the present disclosure, including the four display devices 1g, 1h, 1i, and 1j (display devices including the structure illustrated in FIG. 2B) that are joined to one another. The composite display device 72 includes the display devices each including the structure illustrated in FIG. 2B and arranged to be joined to one another at the side surfaces of the substrates 2 adjoining the side on which the side wiring pads 5 are arranged on the first surface 2a. In this case, the joint pixel pitch of the pixel unit 4 arranged in the outermost array adjacent to the joint side of each of the display devices 1g to 1j can be easily set to substantially the same as the non-joint pixel pitch.

Although embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises. For example, the first side wiring pad 5a located between the adjacent pixel units 4 in the first outermost array 21 may not be between all the adjacent pixel units 4 in the first outermost array 21, and the first side wiring pad 5a may be located between every other adjacent pixel unit 4. The first side wiring pad 5a may also be located in the center between the adjacent pixel units 4. For example, the first side wiring pad 5a may be located with the center point or the center line (a line orthogonal to the first side 2d) in the direction along the first side 2d aligned with the center point or the center line between the adjacent pixel units 4. This structure can reduce electrical short-circuiting of the light emitter and the side wiring pad 5 and improve the yield in mounting the light emitter.

In the display device according to one or more embodiments of the present disclosure, the first wiring pad located between the adjacent pixel units in a direction parallel to and along the first side allows the multiple pixel units arranged in the first outermost array to be in a portion adjacent to the edge on the first surface of the substrate. The joint pixel pitch can thus be easily equalized to the non-joint pixel pitch, although the non-joint pixel pitch is smaller. The resultant display device can display high-definition images with high quality.

The composite display device according to one or more embodiments of the present disclosure can achieve the continuity of a display image at the joint and allows a viewer to feel less discomfort in the display image and the joint to be less noticeable.

### INDUSTRIAL APPLICABILITY

The display device according to one or more embodiments of the present disclosure can be used in various electronic devices. Such electronic devices include, for example, automobile route guidance systems (car navigation systems), ship route guidance systems, aircraft route guidance systems, smartphones, mobile phones, tablets, personal digital assistants (PDAs), video cameras, digital still cameras, electronic organizers, electronic dictionaries, personal computers, copiers, terminals for game devices, television sets, product display tags, price display tags, programmable display devices for commercial use, car audio systems, digital audio players, facsimile machines, printers, automatic teller machines (ATMs), vending machines, digital display watches, smartwatches, and information displays at stations, airports, and other facilities.

The composite display device according to one or more embodiments of the present disclosure can be applied to outdoor display devices that display, for example, news or sports broadcasts, outdoor advertising display devices, display devices installed at stadiums such as a baseball stadium, and display devices installed at, for example, stations and airports for displaying, for example, destinations and times.

The present disclosure may be embodied in various forms without departing from the spirit or the main features of the present disclosure. The embodiments described above are thus merely illustrative in all respects. The scope of the present disclosure is defined not by the description given above but by the claims. Any variations and alterations contained in the claims fall within the scope of the present disclosure.

### REFERENCE SIGNS

| 1, 1a, 1b | display device |
|---|---|
| 2 | substrate |
| 2 a | first surface |
| 2 b | second surface |
| 2 c | side surface |
| 2 d | first side |
| 2 e | second side |
| 2 f | third side |
| 2 g | fourth side |
| 3 | subpixel |
| 4 | pixel unit |
| 34, 35, 36, 37 | insulating layer |
| 5 | side wiring pad |
| 5 a | first side wiring pad |
| 5 a 1 | divided side wiring pad |
| 5 a 2 | divided side wiring pad |
| 5 b | second side wiring pad |
| 5 c | third side wiring pad |
| 5 d | fourth side wiring pad |
| 53, 54 | metal layer |
| 60 | recess |
| 70 | composite display device |

1. A display device, comprising:
a substrate including a display surface;
a plurality of pixel units on the display surface; and
a first wiring pad in a first outermost array of the plurality of pixel units adjacent to a first side on the display surface, the first wiring pad being located between adjacent pixel units of the plurality of pixel units in a direction along the first side.

2. The display device according to claim 1, wherein
a distance between a pixel unit in the first outermost array of the plurality of pixel units and the first side is less than or equal to one-half of a pixel pitch of the plurality of pixel units.

3. The display device according to claim 1, wherein
a distance between the first wiring pad and the first side is less than or equal to one-half of a pixel pitch of the plurality of pixel units, and the first wiring pad is nearer the first side than a pixel unit of the plurality of pixel units in the first outermost array.

4. The display device according to claim 1, wherein
a plurality of the first wiring pads is arranged along the first side.

5. The display device according to claim 1, wherein
the substrate includes
a side surface, and
a side surface wire on the side surface, the side surface wire including an extension extending on the display surface and connected to the first wiring pad.

6. The display device according to claim 1, further comprising:
a second wiring pad in a second outermost array adjacent to a second side on the display surface, the second side adjoining the first side, the second wiring pad being located between adjacent pixel units of the plurality of pixel units in a direction along the second side.

7. The display device according to claim 6, further comprising:
a third wiring pad in a third outermost array adjacent to a third side on the display surface, the third side adjoining the first side and opposite to the second side, the third wiring pad being located between adjacent pixel units of the plurality of pixel units in a direction along the third side.

8. The display device according to claim 1, further comprising:
a fourth wiring pad in a fourth outermost array adjacent to a fourth side on the display surface, the fourth side being opposite to the first side, the fourth wiring pad being located between adjacent pixel units of the plurality of pixel units in a direction along the fourth side.

9. The display device according to claim 1, wherein
the first outermost array includes, at least at one end of the first outermost array, a pixel unit of the plurality of pixel units.

10. The display device according to claim 6, wherein
the second outermost array includes, at least at one end of the second outermost array, a pixel unit of the plurality of pixel units.

11. The display device according to claim 7, wherein
the third outermost array includes, at least at one end of the third outermost array, a pixel unit of the plurality of pixel units.

12. The display device according to claim 8, wherein
the fourth outermost array includes, at least at one end of the fourth outermost array, a pixel unit of the plurality of pixel units.

13. The display device according to claim 1, further comprising:
an insulating layer covering a portion between the first wiring pad and a pixel unit of the plurality of pixel units located adjacent to the first wiring pad.

14. The display device according to claim 13, wherein
the insulating layer includes a recess in the portion.

15. The display device according to claim 1, wherein
the first wiring pad is longer in a direction orthogonal to the first side than in a direction along the first side in a plan view.

16. The display device according to claim 1, wherein
the first wiring pad is wider at a position adjacent to the first side than at a position opposite to the first side in a plan view.

17. A composite display device, comprising:
a plurality of display devices according to claim 1,
the plurality of display devices being joined to one another on side surfaces of the plurality of display devices,
wherein the plurality of display devices includes a first display device and a second display device, and
a portion of a side surface adjoining the first side in the first display device and a portion of a side surface adjoining the first side in the second display device are joined to each other.

18. The composite display device according to claim 17, further comprising:
a light absorber between the portion of the side surface to be joined in the first display device and the portion of the side surface to be joined in the second display device.
